(19) United States
(12) Patent Application Publication
(10) Pub. No.: US 2005/0139144 A1
(43) Pub. Date: Jun. 30, 2005

(54) Method for the production and the use of microparticles and nanoparticles by constructive micronisation

(76) Inventors: Bernd W. Muller, Flintbek (DE); Norbert Rasenack, Kiel (DE)

Correspondence Address: NIXON & VANDERHYE, PC, 1100 N GLEBE ROAD, 8TH FLOOR, ARLINGTON, VA, 22201-4714, US

(21) Appl. No.: 10/508,998

(22) PCT Filed: Mar. 21, 2003
(86) PCT No.: PCT/EP03/02984

(30) Foreign Application Priority Data
Mar. 27, 2002 (DE) 102 14 031.6

(51) Int. Cl. C30B 1/00

(52) U.S. Cl. 117/2

(57) ABSTRACT

The invention relates to a method for producing microparticles and/or nanoparticles of a substance, wherein particles are formed from molecularly distributed substances which simultaneously stabilized in suspension. The substance is dissolved in a solvent system and subsequently a non-solvent for said substance is added whereby said non-solvent can be mixed with the solvent system for this substance. One or several crystal growth inhibitors are added and a rapid merging of solvents and non-solvents take place. The substance is precipitated by forming a dispersion of particles whose size lies in the micrometer or nanometer range.

The invention relates to a process for the preparation of micro- and nanoparticles of solid substances by constructive micronization by means of dissolution and precipitation as well as the use of these small particles.

In pharmacy, the problem has often arisen, above all in recent years, within the framework of the development of new drugs, that the drugs developed by chemical development departments have a very low water solubility or are even water-insoluble. This can limit the bioavailability of the active ingredient or the active ingredients of a drug preparation. For example, this problem occurred in the development of drugs for the immune deficiency syndrome AIDS where therapeutically useful drugs were doomed to failure due to their too low bioavailability. By reducing the crystal size, the dissolution rate can be increased due to the corresponding increase in the specific surface. However, during conventional crushing processes (=destructive micronization), hydrophobic edges and electrostatically-charged, energy-rich areas are produced. This leads to disadvantages which negatively influence the handling of the substances and their processability. The release rate is also not increased to the extent that would be expected by the enlargement of the surface, as a poor wettability often pertains which leads to a floatation. Crushing processes often lead to a broad particle-size distribution with the result that the desired crystal size must then be obtained by fractionation which is not an economical process. This is the case for example with a micronization by means of an air-jet mill. This disadvantage is also described in pharmaceutical technology textbooks (R. H. Müller in R. H. Müller, G. E. Hildebrand, Moderne Arzneiformen, WVG 1997, p. 274). In another overview article which describes micronization using grinding processes, Parrot describes crushing by means of gas-jet mills as “ineffective” (Parrot, E. L., 1990. Comminution. In: Swarbrick, J., Boylan, J. C. (eds.), Encyclopaedia of Pharmaceutical Technology, Vol. 3, Marcel Dekker Inc., New York, p. 101-121).

However even in the case of water-soluble drugs, there is also a need for processes for the preparation of micro- and nanoparticles by constructive micronization. In this context water-soluble is to mean that the water solubility is greater than 1 g/100 ml.

For example, drugs for use in a powder inhaler should display a low agglomeration tendency, good flow properties and a high batch conformity [York, P., Powdered raw materials: Characterizing batch uniformity. Proc. Resp. Drug Del. IV (1994) 83-91]. These requirements often conflict with the properties of a substance crushed by grinding. When grinding larger particles there is little opportunity to influence the particle size and shape and the surface properties and also the electrostatic charge [Malcolmson, R. and Embleton, J. K., Dry powder formulations for pulmonary delivery. PSTT 1 (1998) 394-399]. Alternative micronization processes therefore present themselves which do not require any grinding, but provide the active ingredient with the necessary properties directly during its preparation. Small spherical particles can be formed by spray-drying a solution. Spray-dried active ingredients are however mostly amorphous. However, spray-dried, amorphous disodium cromoglycate (DSCG), on account of an incomplete dispersability, yields only a fine particle fraction between 15% (Rotahaler®) and 36% (Dinkihaler® with 90 l/min) depending on the particle size, air flow and inhaler used [Chew, N. Y. K., Bagster, D. F. and Chan, H. K., Effect of particle size, air flow and inhaler device on the aerolization of disodium cromoglycate powders. Int. J. Pharm. 206 (2000) 75-83). This technique is seldom used for poorly water-soluble active ingredients as the organic solvents necessary here give rise to problems with environmental toxicology and require a high outlay on equipment. In the field of dye chemistry the crystal size likewise plays an important role. For example, dispersions with coarse-crystalline betacarotene are not dyed. Colloidal systems are necessary to achieve a coloration.

Micronization by crushing of difficultly-soluble drugs is a commonly-used method for increasing the dissolution rate. Crushing by means of various forms of milling is a widely used method of preparing small particles. However such a process does not lead to the desired optimum products, among other reasons due to the formation of energy-rich lipophilic edges. One problem is that a floatation often occurs which prevents a substantial dissolution of the active ingredient.

Numerous demands are made by manufacturers, patients, and also by those bearing the costs of the health service, on pharmaceutical preparations, such as for example tablets, dragées or also preparations in capsules, liquid drug forms (suspensions and emulsions) or also drug forms for pulmonary use:
To facilitate the intake by the patient and thus to increase the acceptance by the patient (=patient compliance), tablets should be as small as possible. This means that an optimum tablet formulation should have as high an active-ingredient portion as possible.
On the other hand, by increasing the active ingredient portion in a pharmaceutical preparation, a more economical preparation is possible by saving on adjuvants.
To be able to supply the body efficiently with the active ingredient contained the preparation should be conceived such that it has as high a bioavailability as possible. This means that a tablet should break down rapidly in the gastrointestinal tract and release the active ingredient rapidly. In this context, the demand is to be placed on the active ingredient that, after release has taken place, it has a high dissolution rate. This is of particular importance for drugs where the dissolution rate is the step which determines absorption. In the case of drug forms for pulmonary use, loss by deposition of the particles outside the lungs, which can also lead to undesired drug effects, is to be avoided. The main portion of the applied active ingredient is therefore to reach its action site or resorption site in the lungs.

The processes known from the literature for the preparation of micro- and nanoparticles are mostly processes which achieve a micronization by a crushing of larger particles.

U.S. Pat. No. 5,145,684 describes a wet grinding in the presence of a surface modifier.

U.S. Pat. No. 5,021,242 states a particle crushing by a grinding procedure without adjuvants. An increase in bioavailability by the micronization is described there.

In U.S. Pat. No. 5,202,129 a micronization in the presence of sugar or sugar alcohols by means of milling (“impaction mill” and “high speed stirring mill”) is described.

In U.S. Pat. No. 5,622,938 an “unexpected bioavailability” is described as the result of a micronization process. Here, a wet grinding is described in the presence of a grinding medium which contains surfactant adjuvants as an additive (sugar-based surfactants).

In U.S. Pat. No. 5,747,001 beclomethasone nanoparticles are described which have been prepared by a grinding process in the presence of surface-modified substances.

U.S. Pat. No. 5,091,187 and U.S. Pat. No. 5,091,188 give an overview of various methods for the preparation of nanocrystals for intravenous application, the particles being encapsulated in phospholipids. Only a stabilization of nanocrystals by phospholipids is described. Destructive processes (ultrasound, air-jet milling, high-pressure homogenization) for reducing the particle size but also constructive processes are described there. In the case of constructive processes, drug and phospholipid are dissolved together in an organic solvent and then precipitated together by spray-drying. An “in-flight crystallization” is indicated for this: A solution of drug and lipid is spray-dried. The precipitation takes place while the solution is spray-dried. The particle size is thus determined by the spray-drying process as there are previously no solid particles. Another process described is “solvent dilution”. An organic solution of the lipid and the drug is placed in water as a result of which the drug and the lipid precipitate. The precipitated crystals are obtained by filtration or sedimentation. Both the named constructive processes involve a water-insoluble encapsulation of the crystals by a lipid. In this process the lipophilic active ingredient is dissolved in the organic solvent together with a lipophilic adjuvant. Both, i.e. the active ingredient and the adjuvant, are precipitated by the addition of water.

Pace et al. (Pharmaceutical Technology, 1999 (3), page 116-134) also describe a micronization in the presence of phospholipids. A crushing using shearing forces or impaction by means of homogenization techniques or grinding techniques is described.

U.S. Pat. No. 5,811,609 and WO 91/06292 describe a wet grinding in the presence of hydrocolloids.

According to DE-A-44 40 337 NanoCrystals® are prepared by a high-pressure homogenisation or by means of a grinding process (pearl mill). R. H. Müller describes in an overview article (R. H. Müller, G. E. Hildebrand, Moderne Arzneiformen, WVG 1997, p. 273 ff.) dry-milling in a gas-jet mill, wet grinding in a pearl mill as well as high-pressure homogenization as possibilities for the preparation of nanosuspensions.

A further process often used for crushing by means of a grinding process is high-pressure homogenization. Amorphous nanosuspensions result here due to the high energy density which corresponds to that in a nuclear power station (Müller, R. H., Böhm, H. L., Grau, M. J., 1999. Nanosuspensionen—Formulierungen für schwerlösliche Arzneistoffe mit geringer Bioverfügbarkeit [Nanosuspensions—formulations for difficultly-soluble drugs with low bioavailability]; 1. Herstellung und Eigenschaften [Preparation and Properties]. Pharm. Ind. 61, 74-78).

Generally in all crushing processes the danger of abrasion for example of the grinding balls (of particular importance in the case of a parenteral application) as well as the mechanical and (in particular in the case of dry crushing processes) thermal loading of the product to be ground) is problematic. Air-jet mills lead moreover to a broad particle-size distribution which makes a separation step necessary and also puts the economic feasibility in question.

As already mentioned, constructive processes are also described in the literature. In the case of the known processes however, a very high (>50%) adjuvant portion is often needed with the result that these constitute more of an embedding, which is also reinforced by details of amorphous structures.

Ruch and Matijevic (J. Coll. Interf. Sci 229, 207-211, 2000) ascertain that although there are numerous dispersions of inorganic substances, stable dispersions of organic substances were not successfully described. Exceptions to this are merely polymer lattices as well as the carotenoid dispersions already mentioned above. Other uniform particles of organic substances are not known.

In the process in U.S. Pat. No. 4,540,602 a fine emulsion of the lipophilic drug, dissolved in an organic solvent immiscible with water, is prepared in water in the presence of stabilizers. This process is similar to a standard microencapsulation.

U.S. Pat. No. 4,826,689 describes the precipitation of amorphous organic substances with the aim of using these precipitated substances for an iv application.

U.S. Pat. No. 5,726,642, U.S. Pat. No. 5,665,331 and U.S. Pat. No. 5,662,883 (all Bagchi et al.) describe a microprecipitation using surfactant materials. A condition is however in each case the solution of the drug in a lye and the addition of an anionic surfactant substance which has a molecular structure which corresponds at least 75% to the drug. The precipitation is effected by a pH value displacement in the acidic region.

In U.S. Pat. No. 5,700,471 preparing a preparation with amorphous dye or amorphous drug is described. The substance is melted and the obtained melt is then emulsified in water and spray-dried.

In U.S. Pat. No. 5,133,908 a precipitation is described which leads to a matrix formation. Through the precipitation of a protein a colloidal preparation is formed, the precipitation liquid having a temperature which is higher than the coagulation temperature of the protein. This leads to the formation of spherical particles of the matrix type.

In U.S. Pat. No. 5,118,528 the formation of matrix particles by precipitation is also described. The drug and a film-forming material are precipitated together, spherical particles of the matrix type again resulting.

In U.S. Pat. No. 4,107,288 preparations for use in iv applications are described. Here, the biologically active substance is inserted into a matrix (crosslinked matrix of macromolecules). The crosslinking of the matrix is effected for example by glutaraldehyde.

In U.S. Pat. No. 5,932,245 the preparation of nanoparticles from poorly water-soluble drugs is described. A condition here is however a surface-charging of the drug. Gelatine is used as adjuvant and the pH value is set such that the drug is negatively charged and the gelatine positively charged.

In EP-A-0 410 236 and U.S. Pat. No. 5,364,563 a spray-drying for the preparation of micronized carotene is described.

An emulsion of carotene is dried by means of spray-drying.

Other sources (U.S. Pat. No. 4,522,743, U.S. Pat. No. 5,968,251 (=DE 196 37 517 A1), D. Horn: Preparation and characterization of microdisperse bioavailable carotenoid hydrosols, Die Angewandte Makromolekulare Chemie 166/167, 1989, page 136-153; Information brochure (“Kolloide” [colloids], published by BASF AG, p 50ff. Horn and Rieger in Angewandte Chemie, 2001, 113, 4460-4492) describe a process for the preparation of finely-dispersed, powdery carotene preparations. Gelatine as stabilizer is mainly described, the ratio of carotene to gelatine at 1:2.5 having to be evaluated as extremely unsatisfactory. If the other necessary adjuvants are taken into consideration, a preparation is described which contains only 12.5 wt.-% carotene. Once again, this is therefore more of an embedding. The carotene is present amorphously. The high adjuvant portion has a crystallization-inhibiting action. A further patent (U.S. Pat. No. 4,726,955) describes the use of milk as precipitant, its coagulation in the presence of alcohols being used.

Ruch and Matijevic (J. Coll. Interf. Sci. 229, 207-211, 2000) describe the preparation of budesonide particles in the micrometer range, the process being carried out in part with the help of ultrasound. Compared with the process according to the invention the obtained budesonide particles are not sufficiently stabilized against a particle-size growth. A strong dependency of the particle size on the rate of the drying process is also known. The precipitated dispersions have a particle-size growth and also the dry product cannot be redispersed without the shape and size changing. A broad particle-size distribution as well as an agglomeration of the particles is described.

Gaβmann, List and Sucker (Eur. J. Pharm. Biopharm. 40 (2), 1994, p. 64-72) as well as List and Sucker (U.S. Pat. No. 5,389,382) describe a hydrosol preparation by precipitation in the presence of polyvinyl pyrrolidone (PVP) and poloxamers with subsequent freeze- or spray-drying. An amorphous product is again obtained.

U.S. Pat. No. 4,826,689 describes the preparation of amorphous particles of poorly-soluble drugs by precipitation processes. Generally stability is a problem with amorphous products. No crystallization may occur during the period of use, at different temperatures or even upon further processing. In addition, high adjuvant portions are necessary for stabilization.

Esumi et. al. (Colloids and Surfaces B: Biointerfaces 11, 1998, page 223-229) describe a fine, aqueous suspension. The drug CT 112 forms only suspensions which are hard to stabilize. The described method describes a way of stabilizing, the suspension being formed by adding acid to an alkaline solution which contains PVP and cellulose in addition to the drug. The polymers act as dispersants and also prevent a crystallization. Accordingly, suspension is then present with amorphous solid phase.

A further method of the constructive preparation of micronized substance is precipitation from supercritical gases (Kerc, J., Srcic, S., Knez, Z., Sencar-Bozic, P., 1999. Micronization of drugs using supercritical carbon dioxide. Int. J. Pharm. 182, 33-39; Steckel, H., Thies, J., Müller, B. W., 1997. Micronizing of steroids for pulmonary delivery by supercritical carbon dioxide. Int. J. Pharm. 152, 99-110). A disadvantage of this technique is the high cost of equipment due to the high pressure which is necessary to achieve the supercritical gas.

The object of the present invention is to provide a process with which particles with a size in the micro- and nanometer range can be prepared rapidly, at low cost and with low technical expentiture. At the same time the disadvantages associated with the normal destructive (crushing) processes are to be avoided. Furthermore a possibility is to be offered to prepare rapidly-soluble drug preparations which contain the drug in fine-particle size. Application in other areas is also to be possible where it is desired to use fine-particle poorly-soluble solids. The resulting powder is to have good properties, for example be flowable and display no strong cohesion, which is for example important in the case of pulmonary use, above all in powder inhalers.

The object is achieved according to claim 1 by a process for the preparation of micro- and/or nanoparticles of a substance which is characterized in that the substance is dissolved in a solvent system for it and then a non-solvent for this substance, which is miscible in principle with the solvent system for this substance, is added, one or more crystal growth inhibitors being added and a rapid combining of solvent and non-solvent being carried out as a result of which the substance is precipitated with formation of a dispersion of particles which have a size in the micro- or nanometer range.

Preferred versions are the subject of the dependent claims.

The substance can form a temporary miscibility gap in the solvent with the result that the primary crystallization takes its course in a two-phase system. Similarly the preparation is possible by addition of the substance solution to the non-solvent or by a reciprocal mixing for example in a mixer.

The precipitation, preferably with crystallization, takes place due to a rapidly-occurring supersaturation.

This can be achieved by a “Solvent-Change” process, a “Temperature-Change” process or a “Solvent Evaporation” or a pressure change. A combination of several of these processes is also possible.

Precipitation preferably takes place in the presence of one or more additives which reduce the crystal-size growth of the existing particles, i.e. crystal growth inhibitors.

The solvent system can include one or more solvents for the substance. Suitable solvents can be selected from the group of aliphatic or aromatic alcohols, ketones, nitriles and ethers, in particular they can include isopropanol, ethanol, methanol, acetone and acetonitrile, tetrahydrofurane (THF), propylene glycol, glycerol and dimethyl formamide (DMF). A solution in acidified or alkalified water is also possible with a pH-dependent solubility of the substance.

The process can be applied to all substances with low solubility in the non-solvent used (precipitation medium). In the case of water as precipitant it can therefore be applied to all poorly water-soluble substances (poorly soluble, very poorly soluble, practically insoluble; corresponding to a water solubility smaller than 1 g/100 ml, preferably smaller <0.1 g/100 ml), such as for example to poorly-soluble drugs and vitamins. This poor solubility can also be characterized by the octanol/water distribution coefficient which should preferably be >1.5.

Suitable non-solvents are, naturally depending on the substance in each case, for example one or more selected from water, ketones, short-chained alcohols, DMF, THF, nitrites, glycerol and propylene glycol.

All organic solvents can be considered in principle as non-solvents for water-soluble substances in which the substance has a solubility smaller than 0.1 g/100 ml. Suitable non-solvents can for example be linear or branched C₁-C₁₀ alcohols such as isopropanol, methanol or ethanol, or C₃-C₁₀ ketones such as acetone, or aldehydes such as for example acetaldehyde, or nitrites such as for example acetonitrile or amides such as for example dimethyl formamide.

The process according to the invention enables the preparation of micronized or colloidal powder with an adjuvant portion of clearly below 50 wt.-%. If desired, higher portions of adjuvant can however be used. This is however not necessary for the stability of the particles of the end product which
are characterized by an average particle size of 100 μm to 10 nm, preferably 50 μm to 20 nm, in particular 30 μm to 30 nm and particularly preferably 15 μm to 100 nm,
have a narrow particle-size distribution (this distinguishes them from for example particles crushed by an air-jet mill, which mostly have such a broad particle-size distribution that a fractioning of the product is necessary),
are crystalline or amorphous, preferably however crystalline,
can be used as solid in solid dosage forms such as capsules, tablets or dragées,
have accelerated dissolution properties as well as an improved wettability, the reason being an enlarged wettable surface,
can be parenterally used,
can be incorporated into semisolid systems (e.g. for therapeutic, cosmetic, stabilizing or coloration purposes),
can be administered by inhalation (powder inhaler or suspension aerosol from a pressurized container),
can be used after redispersion in liquid preparations without particle-size growth taking place.

A floatation, as often occurs with a mechanically crushed drug, is not observed.

In addition to the increase in the dissolution rate, the saturation solubility is increased with a clear reduction of the particle size (particularly in the case of a particle size of <1 μm).

As a result of the higher dissolution pressure the drug has an accelerated release. As it can then be distributed in a larger compartment, or be transported away, a recrystallization cannot occur.

When used in suspensions there is no or only an extremely slow sedimentation due to the small particle size. A formed sediment can be very easily shaken up as, due to the small particle size and the narrow particle-size distribution, no caking takes place.

Subject of the invention is also the use of the thus prepared products for the preparation of pharmaceutical dosage forms. Likewise a use in food technology, cosmetics, plant protection or in the field of dye technology is included according to the invention. Use in liquid preparations can also serve for example dye purposes or also therapeutic purposes. The use of a dispersion of colloidal dye pigments (preferably 10 nm-500 nm), for example in an ink, for example for use in ink-jet printer is also possible.

These properties are achieved for example by the process steps described below:

The process used starts from a dissolution of the substance which is poorly or difficultly soluble in the non-solvent or precipitant in a solvent system miscible with this precipitant. In the case of substances difficultly soluble in water (substantial reference to which is made in this description without however limiting it in any way), alcohols such as ethanol, methanol, isopropanol, glycerol and propylene glycol, ketones such as acetone, ethers such as THF, DMF and nitriles such as acetonitrile come into consideration for example as solvents. The use of hydrophobic solvents both as solvent and precipitant is also possible, such as for example dichloromethane, ether, or hydrofluoroalkanes. A dispersion is prepared from this solution by adding the precipitant such as for example water.

The process can also be carried out in reverse, i.e. the substance solution can be added to the precipitant. Even if, in the process according to the invention described here, difficultly-soluble substances in water are predominant, a reversed process, i.e. the precipitation of water-soluble substances with organic precipitants is likewise possible.

In order to further reduce the crystal growth in the case of crystals, crystal growth inhibitors or stabilizers are optionally added.

The dispersion can then be converted to a powder by drying (for example spray-drying, solvent evaporation or freeze-drying), a filtration step or a combination of several of these processes.

The process according to the invention can be carried out discontinuously (i.e. a dispersion is firstly prepared in batches, which is then converted into a dry powder) or also continually (i.e. simultaneous addition of solution and precipitant in a suitable ratio and mixing them for example in a static mixer. Here, precipitation and thus immediate drying of the dispersion formed occurs in the mixer, i.e. directly in front of the spray nozzle of the spray tower). A change of the particle size does not take place during the spray process here either.

As adjuvants for crystal growth inhibiting/stabilizing of the dispersion, which in the case of water as precipitant are preferably water-soluble, the following are suitable for example:
polyvinyl alcohol, PVA
cellulose ether such as for example hydroxypropyl cellulose (HPC), hydroxyethyl cellulose (HEC), hydroxypropyl methylcellulose (HPMC), methyl cellulose (MC), methylhydroxy ethylcellulose (MHEC)
caseinates (such as e.g. calcium caseinate) or casein
sodium alginate
polyvinyl alcohol-polyethylene glycol graft copolymer (e.g. Kollicoat® IR)
polyvinyl pyrrolidone, povidone, PVP
hydroxyethyl starch, HES (such as e.g. HES 130, 400)
polyacrylates/polymethacrylates (such as e.g. Eudragit® L)
chitosan (optionally setting a pH value which leads to a charging of the chitosan)
agar
pectin
sugar such as e.g. trehalose
dextranes (such as e.g. Dextran 20, 60, 200)
gelatine A, gelatine B (optionally setting a pH value which leads to a charging of the gelatine)
gum arabic
surfactants such as for example
   polyoxypropylene-polyoxyethylene-block polymers (poloxamers), (is to be preferred as no micelle formation),
   partial fatty acid esters of polyoxyethylene sorbitan, such as for example polyethylene glycol (20) sorbitan monolau rate, monopalmitate, monostearate, monooleate; polyethyleneglycol (20) sorbitan tristearate and trioleate; polyoxyethylene (5) sorbitan monooleate; polyoxyethylene (4) sorbitan monolaurate (also called polysorbates)
   polyoxyethylene fatty alcohol ethers, such as for example polyoxyethyene (4) lauryl ether, polyoxyethylene (23) lauryl ether, polyoxyethylene (10) cetyl ether, polyoxyethylene (20) cetyl ether, polyoxyethylene (10) stearyl ether, polyoxyethylene (20) stearyl ether, polyoxyethylene (10) oleyl ether, polyoxyethylene (20) oleyl ether (also called macrogol fatty acid ether)
   Polyoxyethylene fatty acid esters, such as for example polyoxyethylene stearate,
   ethoxylated triglycerides, such as polyoxyethylene-glycerol fatty acid ester, such as for example polyoxyethylene glycerol monoisostearate,
   sugar esters (such as e.g. saccharose monolaurate, saccharose monopalmitate, saccharose monostearate, saccharose monomyristate, saccharose monooleate),
   sugar ethers
   alkali soaps (fatty acid salts), such as for example sodium laurate, palmitate, stearate, oleate,
   ionic and zwitterionic surfactants, e.g. betaines, such as for example cocobetaine
   phospholipids.

The use of further adjuvants, such as for example plasticizers, is also possible. Stabilizers can also be included in relation to other functions, e.g. when using oxidation-sensitive substances.

The additives are preferably dissolved in the precipitant but can also be dissolved or suspended in the solvent or non-solvent.

The concentration of crystal growth inhibitors, relative to the substance to be precipitated, is normally in the range of 0.01 to 50 wt.-%, preferably 0.1 to 30 wt.-% and preferably 0.5 to 20 wt.-%.

In a preferred version the invention provides a process for the formation of crystals with clearly reduced crystal size. The crystals can be classed as micronized to colloidal. The process avoids a mechanical crushing of larger crystals, but rather limits the crystal-size growth by suitable measures. It is therefore a constructive process. The resulting crystals display for example a crystal size of 100 μm to 10 nm, preferably 50 μm to 20 nm, in particular 30 μm to 30 nm and particularly preferably 15 μm to 100 nm.

The thus prepared crystals display an accelerated dissolution with the result that, when used in the drugs field for drugs for which the dissolution rate is a step which limits the bioavailability, an accelerated initial resorption in the blood plasma as well as an increase in the bioavailability result.

The thus prepared crystals display in addition—compared with destructive crushing processes—a low cohesiveness. Furthermore they are not electrostatically charged. This enables their use in areas where an easily dispersible powder is required, such as for example in drugs for pulmonary use.

A sterile filtration is possible with a particle size of <400 nm, preferably from <200 nm. This enables preparations of thermolabile active ingredients for parenteral or ophtalmological application to be prepared, as a heat sterilization can be replaced by a sterile filtration.

Itraconazole, ketoconazole, ibuprofen, beclomethasone dipropionate as well as further drugs which satisfy the above-mentioned criteria in terms of poor solubility can be considered as poorly or difficultly-soluble drugs. Mixtures of such drugs can also be used.

Further suitable poorly or difficultly-soluble substances are for example carotenoids such as betacarotene, lycopene, lutein, canthaxanthin, astaxanthin or zeaxanthin.

The prepared particles, in particular crystals, are also suitable for use in colloidal solutions (e.g. aqueous dye solutions of difficultly-soluble dyes).

An exemplary plan of the preparation steps of the process according to the invention is illustrated below:
Dissolution in the mother liquor
Precipitation in non-solvent optionally in the presence of stabilizers
Optional drying (spray-drying, freeze-drying, solvent evaporation)
Optional obtaining of the product by filtration techniques or reverse osmosis and
Optional redispersion.

The particle size is determined directly upon precipitation of the particles and thus during the preparation of the dispersion. The spray-drying does not influence the size of the individual particles. The dispersion presented is merely dried. As the particle size and the particle-size distribution are not determined by the spray-drying process, the spray-drying process can be carried out in cocurrent process. This is particularly preferred for thermolabile substances. Spray towers operating according to the countercurrent process can naturally also be used. Additional processing-adjuvants can also be used, such as for example lactose or mannitol. As a rule however a spray-drying of the dispersion without further adjuvant additives is possible.

A further suitable process for drying is the freeze-drying or the solvent evaporation method or a combination of several processes. Other drying processes can however also be used. Obtaining a product by filtration techniques is also suitable.

The process according to the invention is thus a process which can be used very easily with extremely small outlay on technology almost anywhere, and leads to a high charge level of the end product. As the product is preferably crystalline, its stability is ensured, above all compared to amorphous products described in the literature. A thermal loading such as during grinding processes does not take place.

An advantage of the process according to the invention is the preparation of a micronized drug preparation (or substance preparation) with a (drug) substance portion of over 50 wt.-% (m/m). Compared with customary destructive processes, the process according to the invention has the advantage that no mechanical energy need be used for crushing. Consequently, all crystal surfaces are of natural origin, no areas of varying energy (as result with mechanical crushing) exist. Mechanical crushing results in edges which are as a rule non-polar.

Another process often used to increase the dissolution rate is the encapsulation of a difficultly-soluble drug in cyclodextrines. However cyclodextrine-containing substances have only a very low drug content of as a rule clearly below 50 wt.-% (m/m). A further disadvantage of a complexing with the help of cyclodextrines is that this process cannot be universally used as an affinity of the drug to cyclodextrine is required. For this a specific molecular geometry is primarily necessary. An effective encapsulation can thus be prevented e.g. by large substituents. As a rule there is no connection between the tendency towards complex formation and the physicochemical properties of the drug. In comparison, the use of the process according to the invention described here is related to the physicochemical properties of the drug (e.g. solubility in solvent and insolubility in precipitant). Insolubility for example in water thus represents both the problem of low dissolution rate (and thus low bioavailability) and the solution to the problem. The process according to the invention is thus orientated towards the physicochemical properties of the drug and consequently can be universally used for all (drug) substances which have the named problematic physicochemical properties.

Some embodiments from the pharmaceutical field are given below to illustrate the process according to the invention in more detail without however limiting it in any way. It is shown that the process presented enables a radical increase in the dissolution rate of the solid and can be used with the most varied (drug) substances. Other examples illustrate the suitability of the easily dispersible powder of low cohesion in pulmonary use, where a radical increase in the portion accessible to the lungs is to be observed. The active ingredient preferably reaches its action site, an undesired particle deposition, for example in the throat area, rarely occurs.

### EXAMPLES

### Example 1

### Itraconazole

0.75 g itraconazole are dissolved in 500 ml acetone. For precipitation a 0.005 wt.-% solution of HFMC 4000 (4000 ml) is introduced into water. The solutions are rapidly combined. The particle-size distribution in the resulting dispersion is determined by laser diffraction.

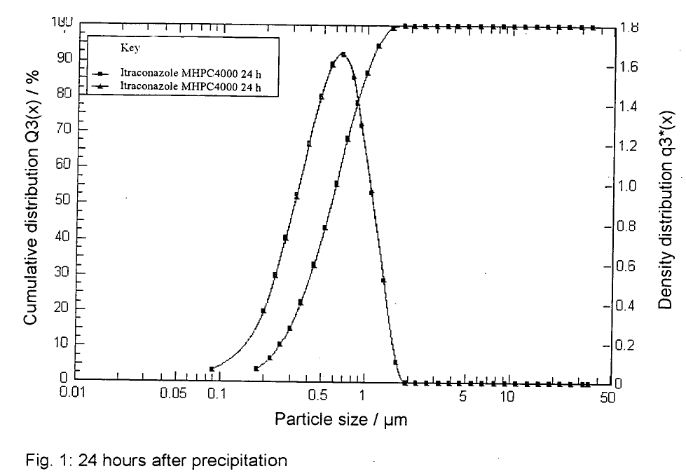

From FIG. 1 it is clear that an effective stabilization was achieved: the particle-size distribution 24 h after precipitation has occurred is shown.

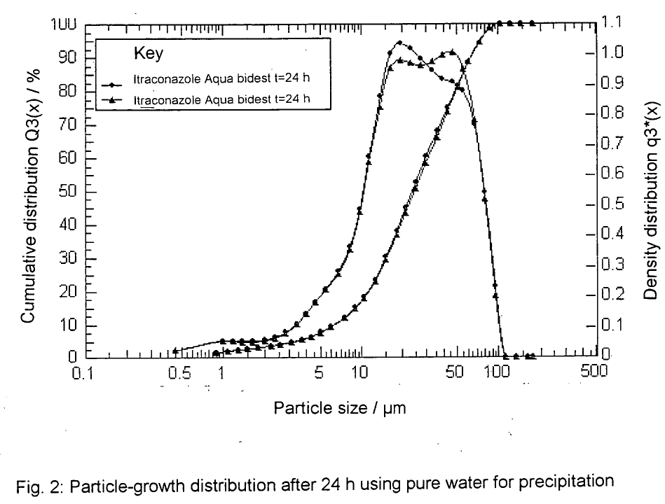

The stabilization of the colloidal state compared with particle-size growth is particularly clear, if precipitation is carried out with water only, without adjuvants (FIG. 2).

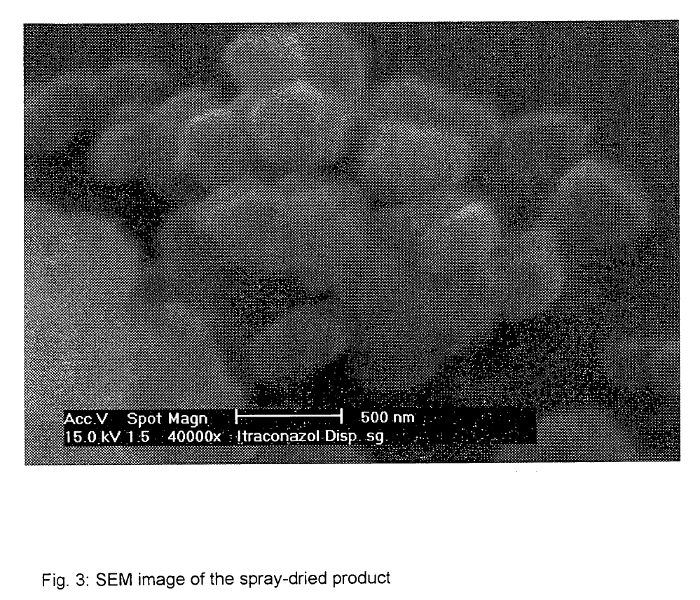

The dispersion is spray-dried (if possible immediately after precipitation; as the particle-size distributions show, intermediate storage is however also possible). The spray-dried product (drug content=78.95 wt.-%) has a particle-size distribution which corresponds to that of the dispersion as is clear from the SEM image (FIG. 3).

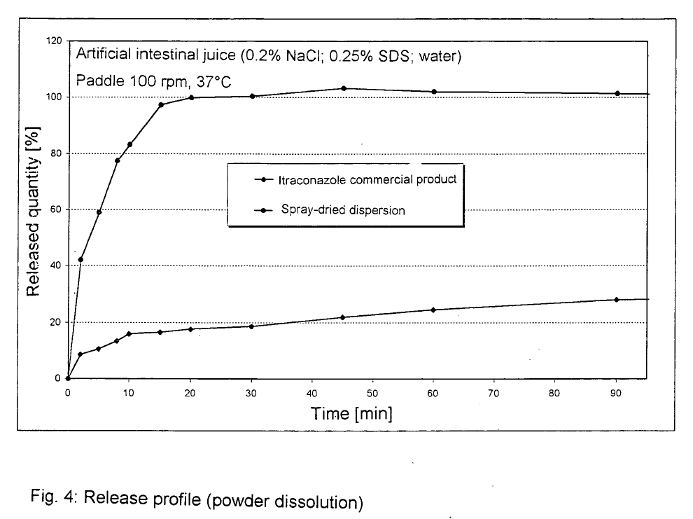

The particle size is consequently already determined during the preparation of the dispersion. The spray drying does not influence the particle size. Only the dispersion presented is dried. The accelerated dissolution rate is shown in FIG. 4.

### Example 2

### Ketoconazole

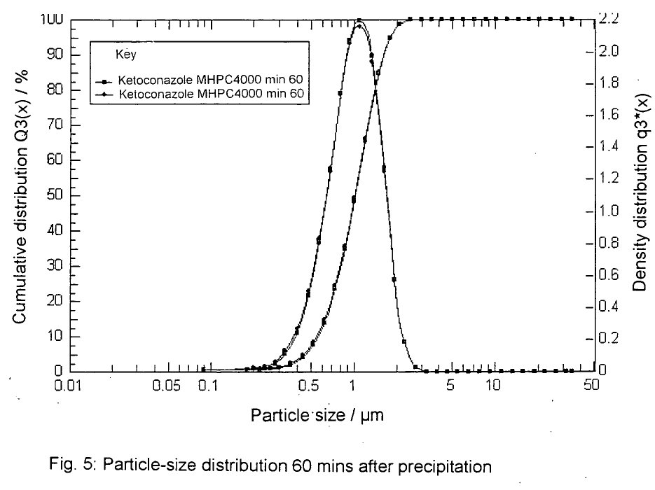

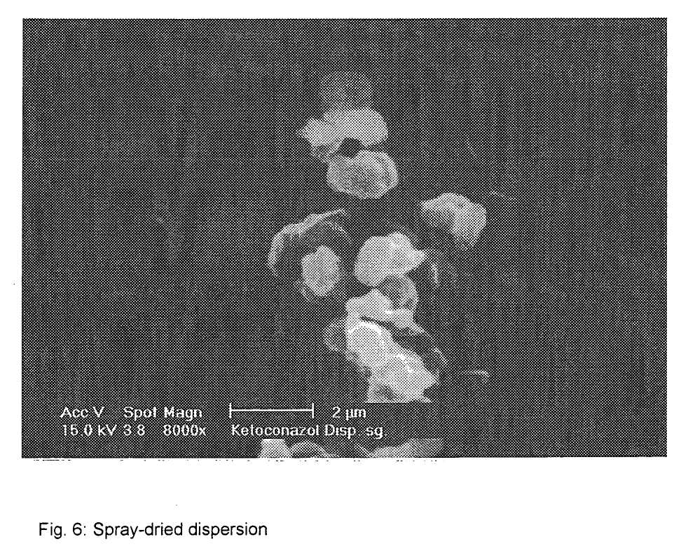

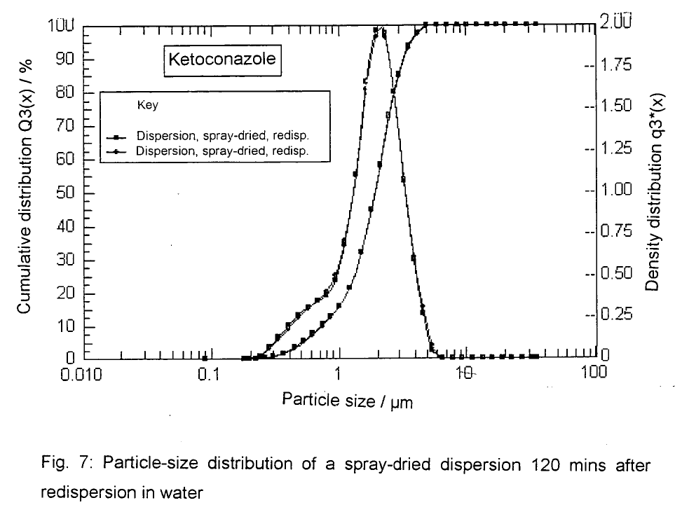

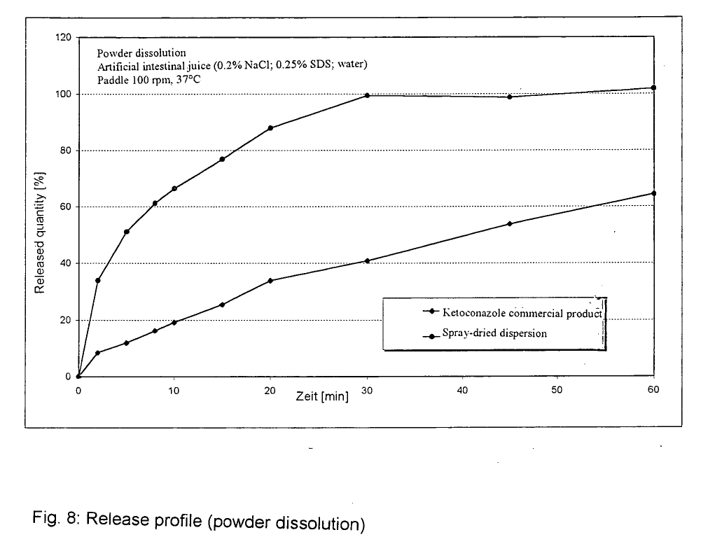

0.5 g ketoconazole are dissolved in 100 ml acetone. For precipitation a 0.025 wt.-% solution of HPMC 4000 (800 ml) is introduced into water. The solutions are rapidly combined. The particle-size distribution in the resulting dispersion is determined by laser diffraction. It is clear from FIG. 5 that an effective stabilization was achieved: particle-size distribution 60 min after precipitation has occurred is shown. The dispersion is spray-dried (if possible immediately after precipitation; as the particle-size distributions show, intermediate storage is however also possible). The spray-dried product (drug content=71.4 wt.-%) has a particle-size distribution which corresponds to that of the dispersion, as is clear from the SEM image (FIG. 6). After redispersion in water a dispersion is obtained the particle-size distribution of which (FIG. 7) corresponds to the spray-dried product, which emphasizes the stability. No particle-size growth is to be found. A clear increase in the release rate is found upon determination of the powder dissolution (FIG. 8).

### Example 3

### Ibuprofen

2.5 g ibuprofen are dissolved in 50 ml isopropyl alcohol. For precipitation a 0.1 wt.-% solution of HPMC 15 (200 ml) is introduced into water. The solutions are rapidly combined.

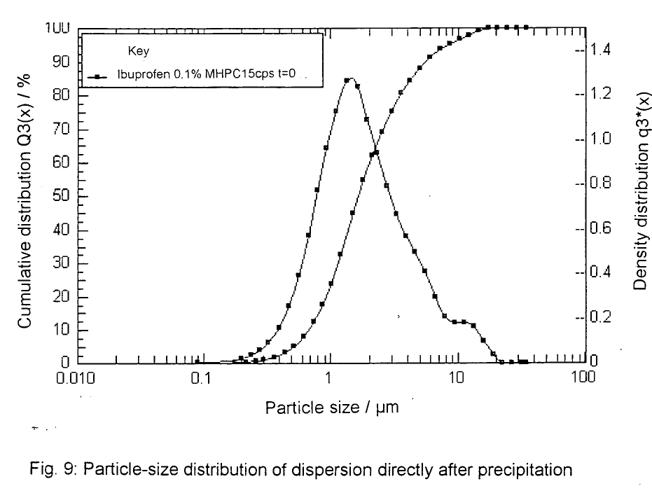

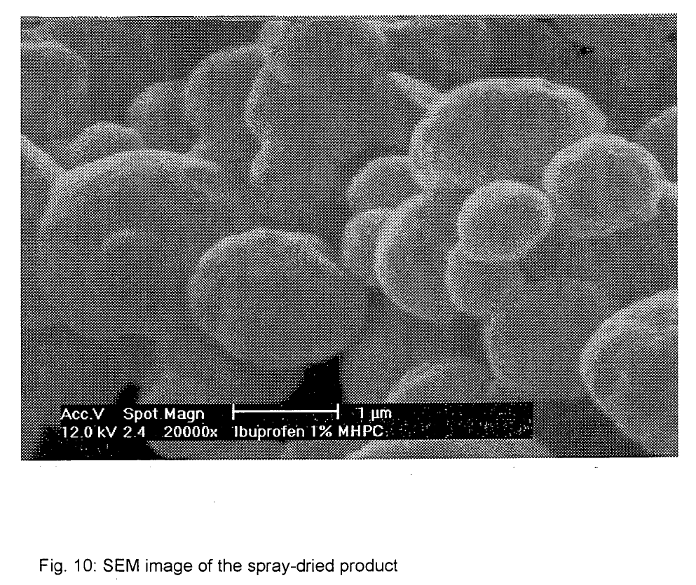

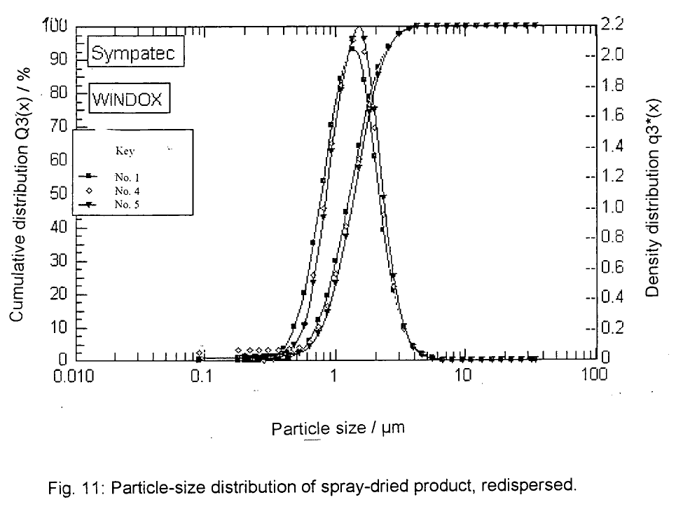

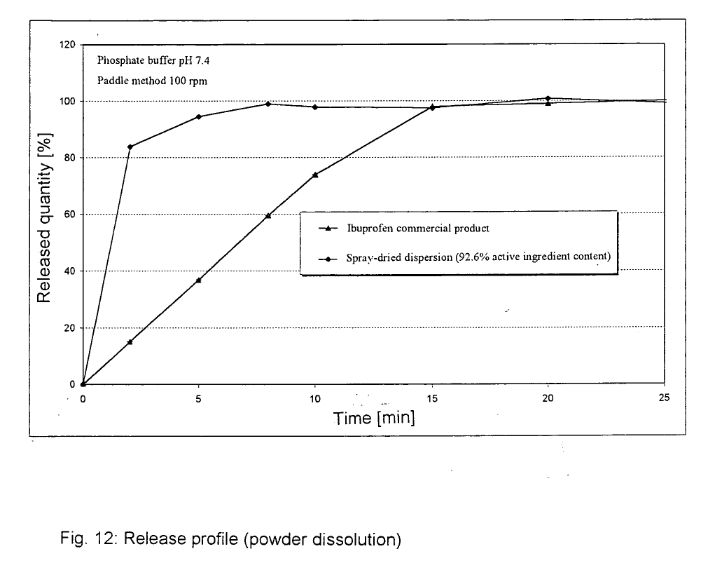

The particle-size distribution in the resulting dispersion is determined by laser diffraction. From FIG. 9, FIG. 10, and FIG. 11 it is clear that an effective stabilization was achieved: particle-size distribution after precipitation has occurred is shown, an average particle size of 1800 nm being present (FIG. 9). The dispersion is spray-dried directly after preparation. The spray-dried product (drug content=92.6 wt.-%) has a particle-size distribution which corresponds to that of the dispersion, as is clear from the SEM image (FIG. 10). After redispersion in water a dispersion is obtained the particle-size distribution of which corresponds to the spray-dried product, which emphasizes the stability. No particle-size growth is to be found. The increase in the dissolution rate is illustrated in FIG. 12.

### Example 4

### Ibuprofen, Continuous Process

25 g ibuprofen are dissolved in 500 ml isopropyl alcohol. For precipitation a 0.1 wt.-% solution of HPMC 15 (2000 ml) is introduced into water. The two solutions are conveyed by means of a hose pump customary in the trade in the ratio 1+4 into a static mixer customary in the trade (e.g. a spiral mixer, Kenics), which is located directly in front of the spray nozzle of the spray tower. The dispersion formed here is consequently dried immediately after its formation. The properties of the formed product correspond to those in Example 3.

### Example 5

### Betacarotene

2.4 g betacarotene, 0.4 g di-alpha-tocopherol and 0.75 g ascorbyl palmitate are suspended in 10 ml isopropyl alcohol. With the addition of 25 ml isopropyl alcohol warming to 175° C. and mixing are carried out for 0.4 seconds, resulting in a solution. Precipitation is then carried out immediately with 200 ml of an aqueous solution which contains 0.1 wt.-% HPMC. This corresponds to a HPMC-carotene ratio of 9.1:90.9. Taking stabilizers into account, an end product with a carotene portion of 62.6 wt.-% is produced. The drying occurs in the spray tower. A colloidal powder results.

### Example 6

### Betacarotene

2.4 g betacarotene, 0.4 g di-alpha-tocopherol and 0.75 g ascorbyl palmitate are suspended in 10 ml isopropyl alcohol. With the addition of 25 ml isopropyl alcohol warming to 175° C. and mixing are carried out for 0.4 seconds, resulting in a solution. Precipitation is then carried out immediately with 220 ml of an aqueous solution which contains 0.2 wt.-% HPMC. This corresponds to a HPMC-carotene ratio of 15.5:84.5. Taking stabilizers into account, an end product with a carotene portion of 59.3 wt.-% is produced. The drying occurs in the spray tower. A colloidal powder results.

### Example 7

### Beclomethasone Dipropionate

The suitability of the process according to the invention for the preparation of pulmonary drugs for application by means of a powder inhaler (DPI) is illustrated in the following example:

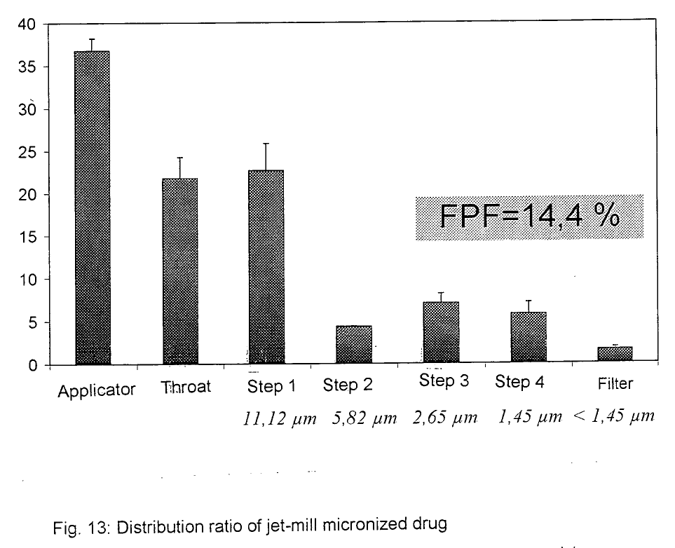

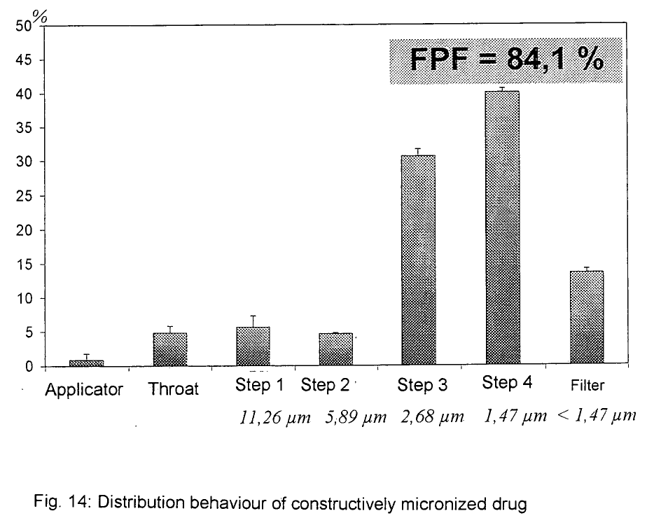

1 g beclomethasone dipropionate is dissolved in 25 ml acetone. For precipitation a 0.01 wt.-% solution of HPMC 50 (400 ml) is introduced into water. The solutions are rapidly combined. The dispersion formed is spray-dried. The spray-dried product displays an even, homogeneous, narrow particle-size distribution. The powder displays only a very low tendency to agglomeration, a very low cohesivity and is not electrostatically charged. The constructively micronized drug is compared with a drug which was micronized using a jet mill. Here a strong agglomeration is shown as well as an electrostatic charge, which leads to problems during the micronization process. Both the constructively micronized drug and the drug micronized using a jet mill are analyzed to determine the respirable fraction using a multi-stage liquid impinger (MSLI) (without addition of further adjuvants). Dramatic differences are shown here: The product micronized using a jet mill has a fine-particle fraction (relative to the drug quantity available in the applicator), FPF of 14.4 wt.-%; 36 wt.-% of the drug remain in the application aid, a further 22 wt.-% are deposited in the throat area (thus reaching the alimentary tract, which can lead to side effects!) and 23% in the upper respiratory tracts. Only 14.4 wt.-% reach their actual target site. However, it is quite different for the destructively micronized drug: here, 84.4 wt.-% of the drug located in the applicator reach their action site in the lungs. The FPF is 84.4 wt.-%. Only 0.8 wt.-% remain in the application aid. Only 4.8 wt.-% of the drug are deposited in the throat area. The distribution of the drug is illustrated in the FIG. 13 and FIG. 14.

### Example 8

### Continuous Process for Beclomethasone Dipropionate

The application of the continuous process for the preparation of drugs for pulmonary application by means of a powder inhaler (DPI) is illustrated in the following example:

100 g beclomethasone dipropionate is dissolved in 2500 ml acetone. For precipitation a 0.01 wt.-% solution of HPMC 50 (400 ml) is introduced into water. These solutions are mixed in the ratio 1+16 in a static mixer (spiral mixer), when precipitation of the drug and thus development of a fine-particle dispersion occurs. This is fed to the spray tower. The resulting micronisate has the same properties as described in Example 7.

### Example 9

### Beclomethasone Dipropionate in Suspension Aerosol

The application of the process for the production of drugs for pulmonary application using a suspension aerosol (preparation in a pressurized container) is illustrated in the following example:

1 g beclomethasone dipropionate is dissolved in 25 ml acetone. For precipitation a 0.01 wt.-% solution of HPMC 50 (400 ml) is introduced into water. The dispersion is spray-dried. The resulting powder is processed in a suspension aerosol (propellant: FKW: HFA227). A uniform suspension results. Here also, a high inhalable fraction and a high content uniformity is observed.

### Example 10

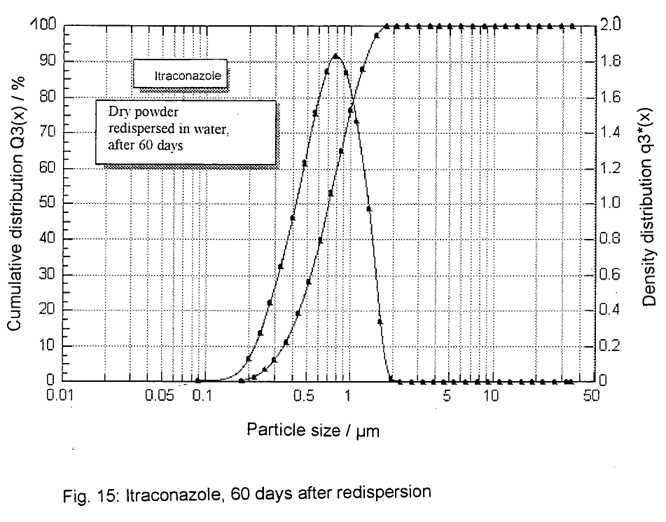

The itraconazole powder from Example 1 is redispersed in water. A uniform dispersion results which is still unchanged after 60 days. The particle-size distribution which was measured 60 days after redispersion is shown in FIG. 15.

### Example 11

### Disodium Cromoglycate (DSCG)

The suitability of the process according to the invention for the preparation of micronized water-soluble drugs (in this example for pulmonary application using a powder inhaler (DPI)) is illustrated in the following example:

4 g disodium cromoglycate are dissolved in 100 ml of a 1% solution of HPMC in water. The precipitation is carried out with isopropanol with rapid combining in the ratio 1:8.

The dispersion formed is spray-dried. The spray-dried product displays a uniform, homogeneous, narrow particle-size distribution. The powder displays only a very small tendency to agglomeration, a very low cohesivity and is not electrostatically charged.

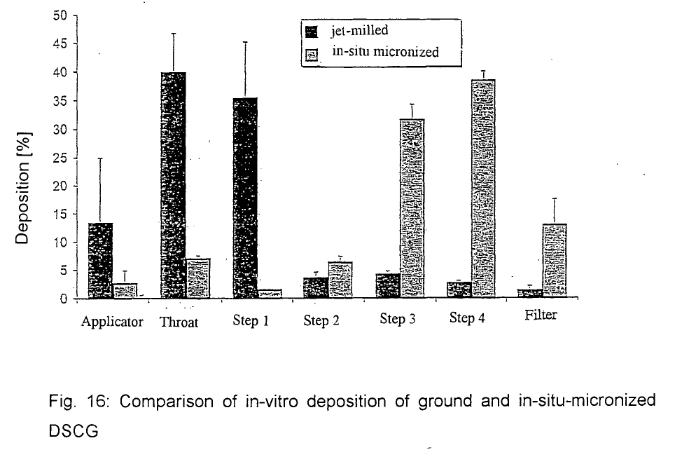

The destructively micronized drug is compared with a drug which was micronized with the aid of a gas-jet mill. Here, a pronounced agglomeration is shown, and also an electrostatic charge, which leads to problems during the micronization process. Both the destructively micronized drug and the drug micronized with the help of a jet mill are analyzed to determine the respiratory fraction with the help of a multi-stage liquid impinger (MSLI) (without the addition of further adjuvants). Dramatic differences are shown here: The product micronized using a jet mill has a fine-particle fraction (relative to the drug quantity available in the applicator), FPF of 7.3 wt.-%. However, it is quite different for the in-situ micronized drug: here, 74.2 wt.-% of the drug located in the applicator reaches their action site in the lungs. The FPF is 74.2 wt.-%. The distribution of the drug is illustrated in FIG. 16.

1. Process for the preparation of micro- and/or nanoparticles of a substance, characterized in that molecularly distributed substances are associated into particles and simultaneously stabilized in suspension, the substance being dissolved in solvent system for it and a non-solvent for this substance subsequently being added which is miscible with the solvent for this substance, one or more crystal growth inhibitor(s) being added and a rapid combining of solvent system and non-solvent being carried out, as a result of which the substance is precipitated with formation of a dispersion of particles which have a size in the micro or nanometer range.

2. Process according to claim 1, characterized in that the solvent system comprises one or more solvents for the substance.

3. Process according to claim 1, characterized in that the solvent system includes one or more solvents selected from aliphatic or aromatic alcohols, ketones, nitrites, in particular ethanol, methanol, isopropanol, acetone and/or acetonitrile.

4. Process according to claim 1, characterized in that the substance in the non-solvent for this substance has a solubility less than 1 g/100 ml, in particular less than 0.1 g/100 ml.

5. Process according to claim 1, characterized in that the non-solvent includes one or more non-solvents selected from water, organic solvent with a hydrophilic character such as methanol.

6. Process according to claim 1, characterized in that the substance is a water-soluble substance and the non-solvent or the mixture of several non-solvents is an organic solvent which is a non solvent for the substance.

7. Process according to claim 6, characterized in that the non-solvent system of one or more non-solyents is selected from aliphatic or aromatic alcohols, ketones, nitrites, aldehydes or amides, in particular from linear or branched C₁-C₁₀ alcohols, preferably isopropanol, methanol or ethanol, C₃-C₁₀ ketones, preferably acetone, acetaldehyde, acetonitrile or dimethyl formamide

8. Process according to claim 1, characterized in that the crystal growth inhibitor(s) is/are selected from polyvinyl alcohols, cellulose ethers, cellulose esters, caseinates, casein, sodium alginate, polyvinyl alcohol-polyethylene glycol graft copolymers, polyvinyl pyrrolidone, povidone, PVP, hydroxyethyl starch, HES, polyacrylates/polymethacrylates, chitosan, agar, pectin, sugar, dextranes, gelatine A, gelatine B, gum arabic, poloxamers, ethoxylated triglycerides, sugar esters, sugar ethers, alkali soaps (fatty acid salts), ionic and zwitterionic surfactants, polysorbates, polyoxyethylene fatty alcohol ethers, polyoxyethylene fatty acid esters and phospholids or any mixtures of same, in particular those selected from the group of hydrophilic polymers.

9. Process according to claim 1, characterized in that the crystal growth inhibitor(s) is/are a cellulose ether selected from the group consisting of hydroxypropyl cellulose, hydroxypropyl methylcellulose, methyl cellulose and methylhydroxy ethylcellulose.

10. Process according to claim 1, characterized in that the crystal growth inhibitor is hydroxypropyl methylcellulose.

11. Process according to claim 1, characterized in that the concentration of crystal growth inhibitors relative to the substance to be precipitated is in the range from 0.01 to 50 wt.-%, preferably 0.1 to 30 wt.-% and preferably 0.5 to 20 wt.-%.

12. Process according to claim 1, characterized in that the particles are present in crystalline form or amorphous form.

13. Process according to claim 1, characterized in that the particles are present in crystalline or amorphous form and have a size of 100 μm to 10 nm, preferably 50 μm to 20 nm, in particular 30 μm to 30 nm and particularly preferably 15 μm to 100 nm.

14. Process according to claim 1, characterized in that that the substance is an active ingredient.

15. Process according to claim 1, characterized in that the substance is a pharmaceutical active ingredient.

16. Process according to claim 1, characterized in that the dispersion is spray-dried or freeze-dried or dried by solvent evaporation or in that the powder is obtained by filtration techniques or in that a combination of a variety of these processes is used.

17. Process according to claim 1, characterized in that the substance micronized according to this process is a substance or drug which has a low cohesivity, a low adhesivity and just an extremely low electrostatic charge.

18. Use of micro- and/or nanoparticles which have been prepared according to a process according to claim 1, for the production of colloidal dispersions.

19. Use of micro- and/or nanoparticles which have been prepared according to a process according to claim 1, for the preparation of drugs, preparations or administration forms which are solid, semi-solid, liquid or to be dispersed in air.

20. Use of micro- and/or nanoparticles which have been prepared according to a process according to claim 1, in drugs in order to increase the dissolution rate and thus the bioavailability of the active ingredient.

21. Use of micro- and/or nanoparticles which have been prepared according to a process according to claim 1, in drugs for parenteral use.

22. Use of-micro- and/or nanoparticles which have been prepared according to a process according to claim 1, in drugs for pulmonary use in a powder inhaler with or without further adjuvants or supports.

23. Use of micro- and/or nanoparticles which have been prepared according to a process according to claim 1, in drugs for pulmonary use in a suspension aerosol (preparation in pressurized container), preferably no further adjuvants being used in addition to the propellant or propellant mixture.
